(19) United States
(12) Patent Application Publication
(10) Pub. No.: US 2016/0113123 A1
(43) Pub. Date: Apr. 21, 2016

(54) Method for Soldering a Circuit Carrier to a Carrier Plate

(71) Applicant: Infineon Technologies AG, Neubiberg (DE)

(72) Inventors: Patrick Jones, Soest (DE); Christoph Koch, Salzkotten (DE); Michael Sielaff, Erwitte (DE)

(21) Appl. No.: 14/886,818

(22) Filed: Oct. 19, 2015

(30) Foreign Application Priority Data
Oct. 20, 2014 (DE) 102014115201.8

(51) Int. Cl. H05K 3/34; B23K 1/00

(52) U.S. Cl. CPC H05K 3/34; B23K 1/0016; H05K 2203/1121

(57) ABSTRACT

A method for soldering a circuit carrier to a carrier plate includes providing a carrier plate having an upper side and a first adjusting device, providing a circuit carrier having an underside and a second adjusting device, providing a solder and placing the circuit carrier onto the carrier plate in such a way that: the underside of the circuit carrier faces the upper side of the carrier plate; the solder is arranged between the carrier plate and the circuit carrier; and the first adjusting device forms a stop for the second adjusting device that limits a displacement of the circuit carrier placed on the carrier plate along the upper side of the carrier plate. After placing the circuit carrier onto the carrier plate, the solder is melted and subsequently cooled down until it solidifies and connects the circuit carrier to the carrier plate in a material-bonding manner at a lower metallization layer.

### PRIORITY CLAIM

This application claims priority to German Patent Application No. 10 2014 115 201.8 filed on 20 Oct. 2014, the content of said application incorporated herein by reference in its entirety.

### TECHNICAL FIELD

The invention relates to the production of a soldered connection between a circuit carrier and a carrier plate, such connections being used for example in the case of electronic modules in which the carrier plate forms a baseplate of the module.

### BACKGROUND

Circuit carriers are usually soldered to the carrier plate. In this case, on the one hand the circuit carriers must be located sufficiently accurately at a predetermined target area of the carrier plate after the soldering operation; on the other hand it is advantageous for the quality of the soldered connection if the circuit carrier floats on the liquid solder during the soldering. The latter may however have the effect that the circuit carrier floats so far as to be outside the target area. This may occur for example if the carrier plate has on the side to which the circuit carrier is to be soldered an unevenness that causes the solder to run away sideways when it melts during the soldering process. In the case of electronic modules, such unevenness often occur whenever the carrier plate is provided with a precurvature before the soldering process, in order to minimize as far as possible later curvatures in the finished assembly, such as occur as a result of different coefficients of thermal expansion of the materials involved. Unwanted floating may for example also occur whenever the side of the carrier plate to which the circuit carrier is to be soldered is in fact planar but is inclined with respect to the horizontal. In the case of electronic modules, the tolerances associated with floating of the circuit carrier may be allowed for in the design of the electrical terminals to be connected to the circuit carrier, but it is nevertheless not permissible for the circuit carriers to float entirely without restriction.

### SUMMARY

A method is provided for soldering a circuit carrier to a carrier plate with which a circuit carrier can be reliably connected to a carrier plate within a predetermined target area.

According to one embodiment, a carrier plate, a circuit carrier and a solder are provided for the soldering of a circuit carrier to a carrier plate. The carrier plate has an upper side, and also a first adjusting device, and the circuit carrier has an underside, and also a second adjusting device. The circuit carrier is placed onto the carrier plate in such a way that the underside of the circuit carrier is facing the upper side of the carrier plate, the solder is arranged between the carrier plate and the circuit carrier, and the first adjusting device forms a stop for the second adjusting device that limits a displacement of the circuit carrier placed on the carrier plate along the upper side of the carrier plate. After that, the solder is melted and subsequently cooled down, until it solidifies and connects the circuit carrier to the carrier plate in a material-bonding manner at a lower metallization layer.

Those skilled in the art will recognize additional features and advantages upon reading the following detailed description, and upon viewing the accompanying drawings.

### BRIEF DESCRIPTION OF THE DRAWINGS

This and further aspects of the invention are explained below on the basis of exemplary embodiments with reference to the accompanying figures, in which:

FIG. 1A shows an assembly with three circuit carriers, which have in each case an upper metallization layer and a dielectric insulation carrier, and also a lower metallization layer, at which they are soldered to a common carrier plate, the carrier plate having for each of the circuit carriers a projection that engages in a cutout in the lower metallization layer of the circuit carrier concerned;

FIG. 1B shows a cross section through a portion of the assembly according to FIG. 1A in a sectional plane E1-E1;

FIG. 1C shows the assembly according to FIG. 1A, in which the upper metallization layer and the insulation carrier have been removed from one of the circuit carriers;

FIGS. 2A-2D show the various steps of a method for soldering a circuit carrier to a carrier plate;

FIG. 3A shows an assembly with three circuit carriers, which have in each case an upper metallization layer and a dielectric insulation carrier, and also a lower metallization layer, at which they are soldered to a common carrier plate, the carrier plate having for each of the circuit carriers two projections, each of which engages in a cutout in the lower metallization layer of the circuit carrier concerned;

FIG. 3B shows the assembly according to FIG. 3A, in which the upper metallization layer, the insulation carrier and the solder layer have been removed from one of the circuit carriers;

FIG. 3C shows a cross section through one of the projections of the carrier plate of the assembly according to FIG. 3A in a sectional plane E2-E2;

FIG. 3D shows a cross section through another of the projections of the carrier plate of the assembly according to FIG. 3A in a sectional plane E3-E3;

FIG. 4A shows an assembly with three circuit carriers, which have in each case an upper metallization layer and a dielectric insulation carrier, and also a lower metallization layer, at which they are soldered to a common carrier plate, the carrier plate having a multiplicity of projections, each of which engages in a cutout in the lower metallization layer of at least one of the circuit carriers;

FIG. 4B shows the assembly according to FIG. 4A, in which two of the circuit carriers including the associated solder layers have been removed and in which the upper metallization layer and the insulation carrier have been removed from the third of the circuit carriers;

FIG. 4C shows the assembly according to FIG. 4A, in which the upper metallization layer and the insulation layer have been respectively removed from all of the circuit carriers;

FIG. 5 shows the limitation of a linear displaceability between a circuit carrier and a carrier plate that is brought about by an adjusting device; and

FIG. 6 shows the rotational limitation between a circuit carrier and a carrier plate that is brought about by an adjusting device.

### DETAILED DESCRIPTION

The representation in the figures is not to scale. Unless otherwise specified, in the figures the same designations denote elements that are the same or have the same effect.

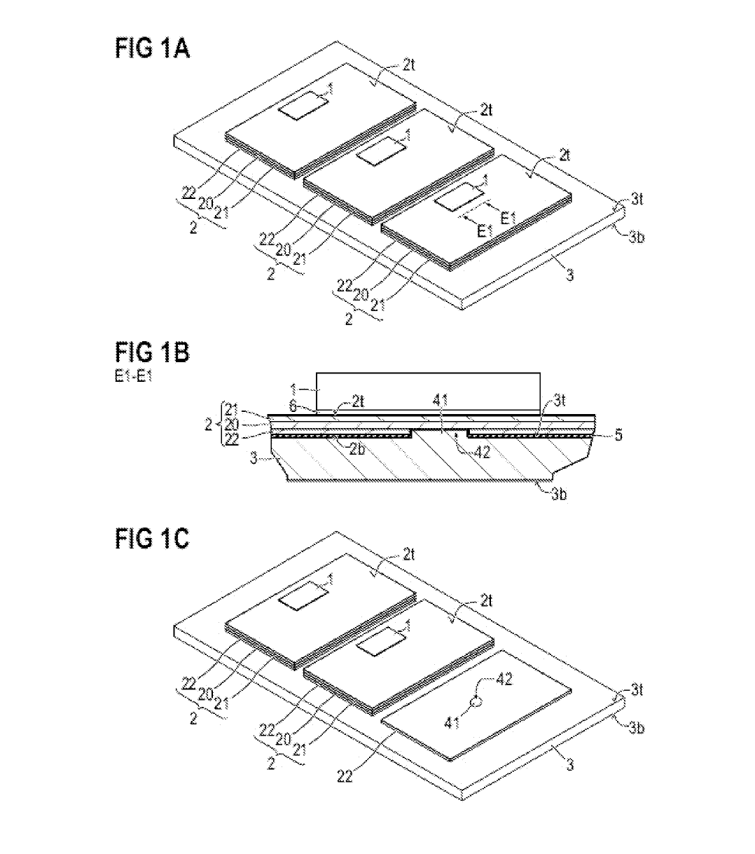

FIG. 1A shows a perspective view of an assembly with three circuit carriers 2, which are jointly soldered onto the upper side 3t of a carrier plate 3. Each one of the circuit carriers 2 has an upper side 2t, and also an underside 2b, which is opposite from the upper side and in FIG. 1A is concealed (see FIG. 1C). The upper side 2t may, optionally in each case, be populated with one or more semiconductor chips 1.

The circuit carrier 2 also has a dielectric insulation carrier 20, to which an upper metallization layer 21 has been applied, and also an optional lower metallization layer 22, which are located on sides of the insulation carrier 20 opposite from one another. The upper metallization layer 21 may, if required, be structured, so that it has conductor tracks, which can be used for example for electrical interconnection and/or for mounting chips. The dielectric insulation carrier 20 can be used for the purpose of electrically insulating the upper metallization layer 21 and the lower metallization layer 22 from one another.

The circuit carrier 2 may be, for example, a ceramic substrate, in which the insulation carrier 20 is formed as a thin layer which comprises ceramic or consists of ceramic. Metals with good electrical conduction, such as for example copper or copper alloys, aluminum or aluminum alloys, but also any other metals or alloys, are suitable as materials for the upper metallization layer 21 and, if present, the lower metallization layer. If the insulation carrier 20 comprises ceramic or consists of ceramic, the ceramic may for example be alumina (Al₂O₃) or aluminum nitride (AlN) or zirconia (ZrO₂), or a mixed ceramic which, in addition to at least one of the ceramic materials mentioned, also comprises at least one other ceramic material different from it. A circuit carrier 2 may for example be formed as a DCB substrate (DCB=Direct Copper Bonding), a DAB substrate (DAB=Direct Aluminum Bonding), an AMB substrate (AMB=Active Metal Brazing) or an IMS substrate (IMS=Insulated Metal Substrate). The upper metallization layer 21 and the lower metallization layer 22 may, independently of one another, have in each case a thickness in the range from 0.05 mm to 2.5 mm. The thickness of the insulation carrier 20 may for example lie in the range from 0.1 mm to 2 mm. However, thicknesses greater or smaller than the thicknesses specified are likewise possible. The thicknesses are in this case respectively to be determined in a direction perpendicular to the underside 2b of the circuit carrier 2.

The carrier plate 3 may for example be formed as a metal plate. It may for example consist completely or to at least 90% of copper, aluminum or a copper-aluminum alloy, or of a metal-matrix composite material (MMC=Metal Matrix Composite). Optionally, it may also have on its upper side 3t a thin coating, for example an electrodeposited nickel layer, in order to improve the solderability.

If a circuit carrier 2 is populated with one or more optional semiconductor chips 1, the circuit carrier 2 may be pre-populated with these semiconductor chips 1 and then soldered in the pre-populated state together with the semiconductor chip or chips 1 to the carrier plate 3. Each such semiconductor chip 1 may contain any desired electronic component, for example a MOSFET (Metal Oxide Semiconductor Field Effect Transistor), an IGBT (Insulated Gate Bipolar Transistor), a thyristor, a JFET (Junction Field Effect Transistor), an HEMT (High Electron Mobility Transistor), a diode, etc.; alternatively or additionally, also any one or more other active or passive electronic components.

The upper side 2t of the circuit carrier 2 represents its component side and is provided by the side of the circuit carrier 2 that is facing away from the carrier plate 3, while the side of the circuit carrier 2 that is facing the carrier plate 3 forms its underside 2b. The underside 2b of the circuit carrier 2 serves the purpose of connecting it to the carrier plate 3 in a material-bonding manner.

FIG. 1B shows a cross section through a portion of the assembly according to FIG. 1A in a sectional plane E1-E1. As can be seen here, the circuit carrier 2 is connected to the carrier plate 3 in a material-bonding manner by means of a solder layer 5. For this purpose, the solder layer 5 adjoins both the upper side 3t of the carrier plate 3 and the side of the lower metallization layer 22 that is facing away from the insulation carrier 20, and consequently the underside 2b of the circuit carrier 2. An optional semiconductor chip 1 is connected to the upper metallization layer 21 in a material-bonding manner by means of a connecting layer 6 on the upper side 2t of the circuit carrier 2. The connecting layer 6 may for example be a solder layer, in particular a diffusion solder layer, or a layer with a sintered metal powder (e.g. a silver powder), or an electrically conducting or electrically insulating adhesive layer.

The carrier plate 3 also has a projection 41, which engages in a cutout 42 in the circuit carrier 2, here a cutout in the lower metallization layer 22. As explained in still more detail below, the projection 41 serves the purpose of limiting floating of the circuit carrier 2 during the liquid state of the solder 5 during the soldering of the circuit carrier 2 to the carrier plate 3.

FIG. 1C shows the already explained assembly according to FIG. 1A, the upper metallization layer 21 and the insulation carrier 20 having been removed in the case of one of the circuit carriers 2 for purposes of explanation. It can be seen in this representation that a cutout 42 may be formed as a through-opening in the lower metallization layer 22.

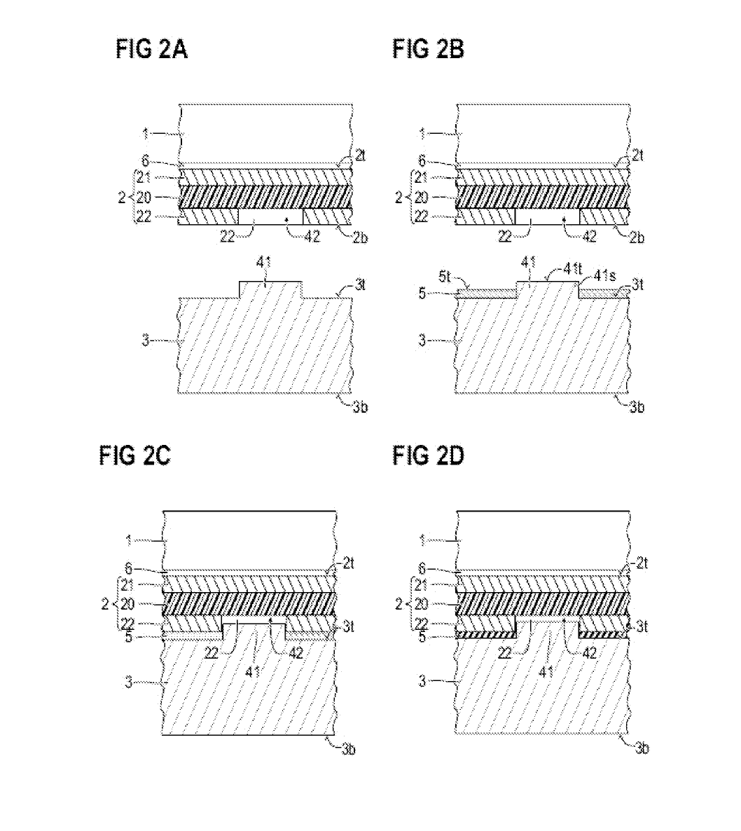

A method for producing an assembly in which a circuit carrier 2 is soldered onto a carrier plate 3 is explained below on the basis of FIGS. 2A to 2D. The same sectional plane through a portion of the circuit carrier 2 and the carrier plate 3 is represented in each case.

FIG. 2A shows a portion of a carrier plate 3 and a portion of a circuit carrier 2. The carrier plate 3 has an upper side 3t and an underside 3b that is opposite from the upper side 3t. Similarly, the circuit carrier 2 also has an upper side 2t and an underside 2b that is opposite from the upper side 2t. As already explained, the upper side 2t of the circuit carrier 2 may be optionally pre-populated with one or more electronic components, here for example with a semiconductor chip 1, which is connected to the circuit carrier 2 in a material-bonding manner by means of a connecting layer 6, which adjoins both the semiconductor chip 1 and the upper side 2t.

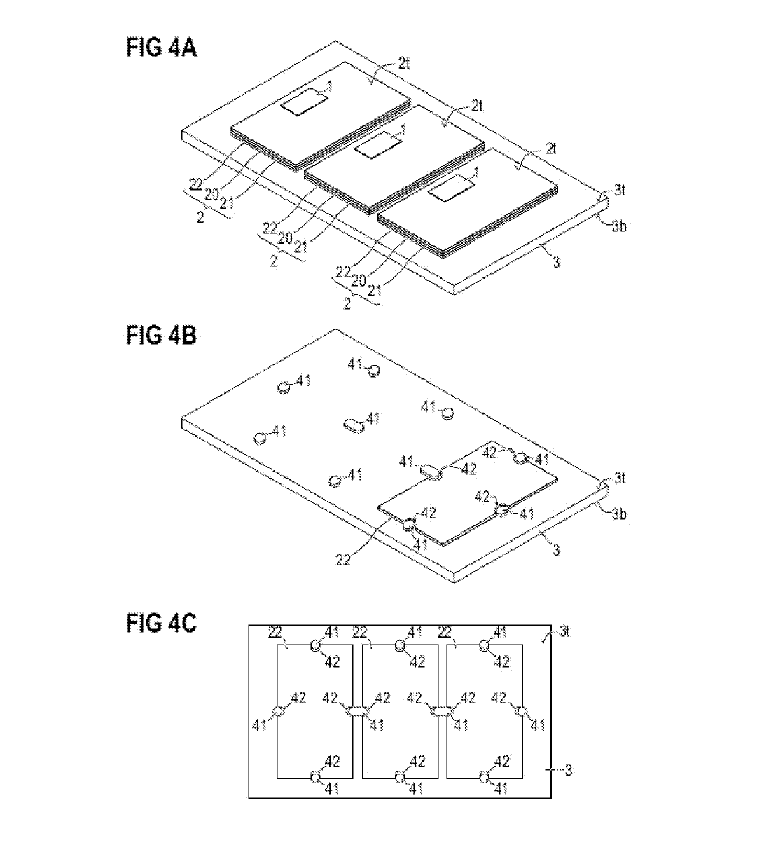

The lower metallization layer 22 has a cutout 42, which may optionally extend up to the insulation carrier 20. Alternatively, the cutout 42 may also be formed as a blind hole in the lower metallization layer 22, which extends from the underside 2b into the lower metallization layer 22 in the direction of the insulation carrier 20, but does not reach up to it. Irrespective of whether or not it extends up to the insulation carrier 20, the cutout may in this case be formed as a through-opening in the lower metallization layer 22 that is annularly surrounded by the lower metallization layer 22, but also as a groove that extends laterally into the lower metallization layer 22, which is explained later on the basis of FIGS. 4B and 4C.

As also shown in FIG. 2B, then a solder 5 is positioned between the circuit carrier 2 and the carrier plate 3. For example, the solder 5 may be applied as a paste to the upper side 3t of the carrier plate 3 or be placed as a preformed, solid solder platelet onto the upper side 3t of the carrier plate 3. In the case of a solid solder platelet, it may have in the region of the projection 41 a cutout through which the projection 41 extends. In any event, the projection 41 can protrude beyond the upper side 5t of the solder 5 applied to or placed on the upper side 3t of the carrier plate 3 in a direction away from the underside 3b of the carrier plate 3.

FIG. 2C shows the pre-populated circuit carrier 2 placed on the carrier plate 3 indirectly by way of the solder 5. In this state, the solder 5 contacts both the upper side 3t of the carrier plate 3 and the underside 2b of the circuit carrier 2. Since, as explained, the projection 41 protrudes beyond the upper side 5t of the solder 5, the protruding part 41s of the projection 41 can still engage in the cutout 42, and consequently limit sideways floating of the circuit carrier 2 on the melted solder 5 during the subsequent soldering process, and consequently prevent undesired floating of the circuit carrier 2 resting on the carrier plate 3.

FIG. 2D shows the finish-soldered assembly with the carrier plate 3 and the circuit carrier 2. The solder 5, which has solidified again after melting, adjoins both the upper side 3t of the carrier plate 3 and the underside 2b of the circuit carrier 2 and securely connects them to one another. Even after the solder 5 has solidified, the projection 41 engages in the cutout 42.

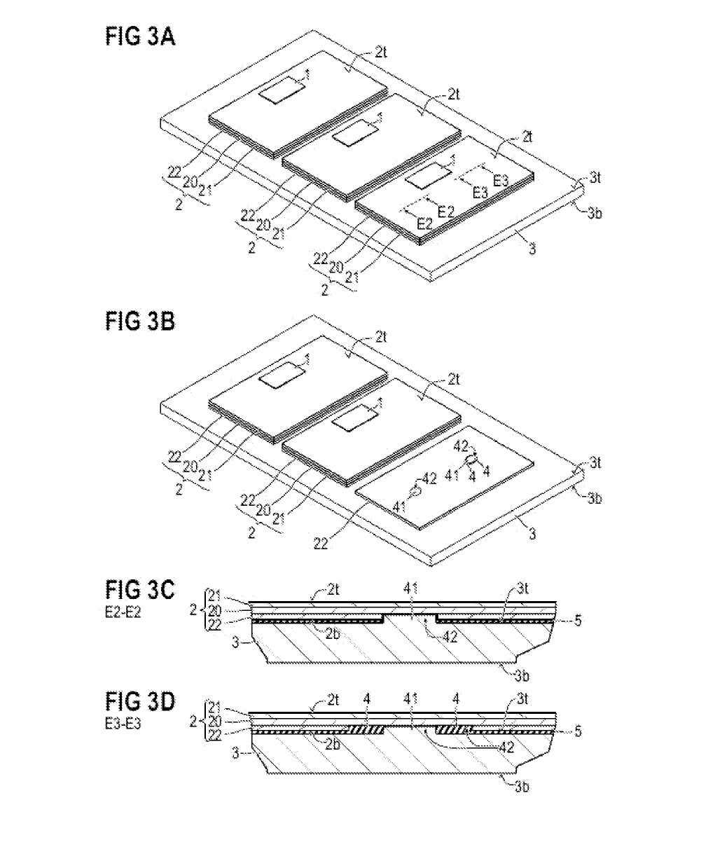

FIG. 3A shows an arrangement corresponding to FIG. 1A, but with the difference that the carrier plate 3 has for each of the circuit carriers 2 at least two projections 2, each of which engages in a cutout 42 in the lower metallization layer 22 of the circuit carrier 2 concerned. Each of these projections 41 can be used in the same way, such as that which has already been explained with reference to the foregoing figures.

The use of two or more spaced-apart projections 41 allows not only reliable limitation of linear floating of the circuit carrier 2 floating on the liquid solder 5 but also rotation. In principle, however, rotation can also be achieved with only one projection 41 and only one cutout 42, if their geometries are correspondingly made to match one another. Although the geometries of a projection 41 and a cutout 42 can in principle be chosen as desired, reliable and precise limitation of rotation requires that the projection 41 and the cutout 42 then extend over a great range in the lateral direction. This may, however, be disadvantageous for example if the waste heat that occurs in a semiconductor chip 1 arranged on the upper side 2t of the circuit carrier 2 is to be removed by way of the circuit carrier 2 and the carrier plate 3, because there is no thermal contact, or not particularly good thermal contact, between the circuit carrier 2 and the upper side 41t of the projection 41 (see FIG. 2B) that is facing the circuit carrier 2.

FIG. 3B shows the already explained assembly according to FIG. 3A, the upper metallization layer 21 and the insulation carrier 20 having been removed in the case of one of the circuit carriers 2 for purposes of explanation. It can be seen in this representation that each of the projections 41 of the carrier plate 3 engages in a cutout 42 of its own in the lower metallization layer 22 of the circuit carrier 2.

FIG. 3C shows a cross section through a first portion of the assembly according to FIG. 3A in a sectional plane E2-E2, and FIG. 3D shows a cross section through a second portion of the assembly according to FIG. 3A in a sectional plane E3-E3. The sections according to FIGS. 3C and 3D respectively run through one of the two projections 41 of the carrier plate 3 and the associated cutout 42 in the lower metallization layer 22. As FIGS. 3B and 3D reveal, as long as it is formed as a through-opening in the lower metallization layer 22, a cutout 42 may not only have a circular cross section but may also be formed as a slot. Such a refinement may be used for the purpose of allowing a relative mobility between the circuit carrier 2 and the carrier plate 3 in one direction in order to avoid stresses that may occur as a result of different coefficients of thermal expansion of the circuit carrier 2 and the carrier plate 3. In spite of the projection 41 engaging in the cutout 42, before the circuit carrier 2 is soldered onto the carrier plate 3, the cutout 42 still has a clearance 4, which is at least partially filled with solder 5 during the subsequent soldering, the result of which is shown in FIG. 3D.

FIG. 4A shows a perspective view of an assembly with three circuit carriers 2, which have in each case an upper metallization layer 21 and a dielectric insulation carrier 20, and also a lower metallization layer 22, at which they are soldered to the upper side 3t of a common carrier plate 3.

FIG. 4B shows the already explained assembly according to FIG. 4A, two of the circuit carriers 2 including the associated solder layers 5 having been removed for purposes of explanation, and the upper metallization layer 21 and the insulation carrier 20 having been removed in the case of the third of the circuit carriers 2. It can be seen in this representation that a cutout 42 does not necessarily have to be formed as a through-opening in the lower metallization layer 22, but may also extend from the lateral periphery of the lower metallization layer 22 into it.

FIG. 4C shows once again the assembly according to FIG. 4A, the upper metallization layer 21 and the insulation layer 20 having been removed in the case of each of the three circuit carriers 2 for purposes of explanation. It can be seen in this representation that a projection 41 may optionally engage in the cutouts 22 in the lower metallization layers 22 of two neighboring circuit carriers 2.

FIG. 5 shows an arrangement in which a circuit carrier 2 is soldered onto a carrier plate 3, during the soldering operation, the upper metallization layer 21 and the insulation carrier 20 not being shown in order to demonstrate the operating mode of the arrangement comprising the projections 41 and cutouts 42 of the lower metallization layer 22. Shown are the two extreme positions, respectively denoted by 22 and 22′, that the circuit carrier 2 and the lower metallization layer 22 on the carrier plate 3 can assume when there is a linear displacement in a direction r parallel to the underside 2b of the circuit carrier 2. The maximum displaceability, i.e. the maximum play in the direction r, is denoted by Δr. The maximum play Δr along the upper side 3t of the carrier plate 3 of the circuit carrier 2 placed on the carrier plate 3 can be chosen such that it is at least 0.1 mm and/or at most 0.4 mm. This criterion may optionally apply to one or more or all of the lateral directions r, i.e. the directions parallel to the underside 2b of the circuit carrier 2.

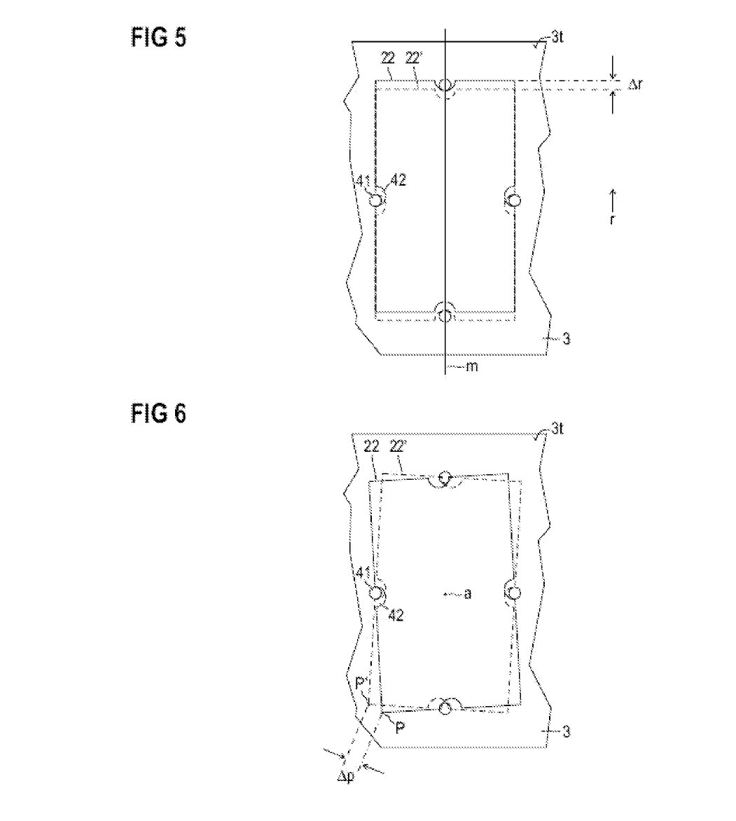

By analogy thereto, FIG. 6 shows the same arrangement, but shown here are the two extreme positions that the circuit carrier 2 and the lower metallization layer 22 on the carrier plate 3 can assume when there is a rotation about an axis of rotation a perpendicular to the underside 2b of the circuit carrier 2. The projections 41 and cutouts 42 are arranged and dimensioned in such a way that they limit a rotation of the circuit carrier 2 placed onto the carrier plate 3 about an axis of rotation a perpendicular to the underside 2b of the circuit carrier 2. The geometry can be optionally chosen such that for each location of the circuit carrier 2 it is the case that the distance Δp between the two farthest apart positions P, P′ that this location can assume within the confines of the limitation on the carrier plate 3 is a maximum of 0.4 mm. This is represented in FIG. 6 by the example of the left-hand lower corner of the circuit carrier 2. In the rotational position denoted by 22, the left-hand lower corner of the circuit carrier 2 is at the position P on the carrier plate 3, and, in the rotational position denoted by 22′, it is at the position P′. When there is a rotation about the axis a within the limitation predetermined by the projections 41 and cutouts 42, the lower left-hand corner of course passes over still further positions on the carrier plate 3. The distance of the two farthest apart positions, here that is the distance Δp between the positions P and P′, can be chosen such that it is a maximum of 0.4 mm. The geometry of the adjusting devices may be made to match in such a way that this criterion applies to all of the locations of the circuit carrier 2.

The previously explained projections 41 form an adjusting device of the carrier plate 3, and the cutouts 42 form an adjusting device of the circuit carrier 2. By analogy thereto, it would also be possible that an adjusting device of the carrier plate 3 has one or more cutouts, which respectively extend from the upper side 3t of the carrier plate 3 into it, and that an adjusting device of the circuit carrier 2 has one or more projections, which are formed as projections of the lower metallization layer 22 and extend away from the insulation carrier 20 on the side of the lower metallization layer 22 that is facing away from the insulation carrier 20. Each one of these projections can then engage in one of the cutouts in the carrier plate 3 during the soldering of the circuit carrier 2 and limit a linear displacement and/or a rotation of the circuit carrier 2 floating on the solder 5.

Irrespective of whether projections 41 are formed on the lower metallization layer 22 or on the carrier plate 3, they may for example be produced by stamping. Cutouts 42 in the lower metallization layer 22 or the carrier plate 3 may be created for example by drilling or milling.

Furthermore, cutouts 42 in the lower metallization layer 22 may already be created in it before the lower metallization layer 22 is connected to the insulation carrier 20. Thus, for example, one or more cutouts 42 may be stamped into a metal foil and the metal foil then connected to the insulation carrier 20 together with a further metal foil, which later forms the upper metallization layer 21.

If only one projection 41, which is formed either on the lower metallization layer 22 of the circuit carrier 2 or on the carrier plate 3 and engages in a cutout 42 in the carrier plate 3 or the lower metallization layer 22, is used for limiting the floating of a circuit carrier 2, the projection 41 that is formed on the lower metallization layer 22 or the cutout 42 that is formed in the lower metallization layer 22 may for example be located in the region of the middle of the circuit carrier 2, see for example FIG. 1C.

If, otherwise, two projections 41, which are formed either on the lower metallization layer 22 of the circuit carrier 2 or on the carrier plate 3 and respectively engage in a cutout 41 in the carrier plate 3 or the lower metallization layer 22 are used for limiting the floating of a circuit carrier 2, the projections 41 that are formed on the lower metallization layer 22 or the cutouts 42 that are formed in the lower metallization layer 22 may for example be located on a center parallel m of two opposite side edges 2k of the circuit carrier 2, see for example FIG. 5.

In principle, irrespective of whether it is formed on the lower metallization layer 22 or on the carrier plate 3, a projection 41 may have any desired cross section. One possible variant is for example a circular cross section. Furthermore, irrespective of whether it is formed on the lower metallization layer 22 or on the carrier plate 3, a cutout 42 may have any desired cross section. One possible variant is for example a circular cross section, or an approximately U-shaped cross section.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for soldering a circuit carrier to a carrier plate, the method comprising:
providing a carrier plate having an upper side and a first adjusting device;
providing a circuit carrier having an underside and a second adjusting device;
providing a solder;
placing the circuit carrier onto the carrier plate in such a way that:
the underside of the circuit carrier faces the upper side of the carrier plate;
the solder is arranged between the carrier plate and the circuit carrier; and
the first adjusting device forms a stop for the second adjusting device that limits a displacement of the circuit carrier placed on the carrier plate along the upper side of the carrier plate; and
after placing the circuit carrier onto the carrier plate, melting the solder and subsequently cooling down the melted solder until it solidifies and connects the circuit carrier to the carrier plate in a material-bonding manner at a lower metallization layer.

2. The method of claim 1, wherein the circuit carrier rests indirectly on the carrier plate after placement.

3. The method of claim 2, wherein after placement of the circuit carrier on the carrier plate, the solder contacts the circuit carrier and the circuit carrier does not contact the carrier plate.

4. The method of claim 1, wherein the first adjusting device forms a stop for the second adjusting device that limits a displacement of the circuit carrier placed on the carrier plate in a direction along the upper side of the carrier plate and/or limits a rotation of the circuit carrier placed on the carrier plate.

5. The method of claim 1, wherein the first adjusting device forms a stop for the second adjusting device that allows a linear displacement of the circuit carrier placed on the carrier plate in any direction parallel to the underside of the circuit carrier with a play of at least 0.1 mm and/or a play limited to a maximum of 0.4 mm.

6. The method of claim 1, wherein the first adjusting device forms a stop for the second adjusting device that limits a rotation of the circuit carrier placed on the carrier plate about an axis of rotation perpendicular to the underside of the circuit carrier such that for each location of the circuit carrier, the distance between two farthest apart positions that this location can assume within the confines of the limitation on the carrier plate is a maximum of 0.4 mm.

7. The method of claim 1, wherein one of the adjusting devices has one or more projections and the other adjusting device has one or more cutouts, each projection engaging in one of the cutouts when the circuit carrier is placed on the carrier plate.

8. The method of claim 1, wherein the circuit carrier has a dielectric insulation carrier and a first metallization layer and a second metallization layer applied to opposing sides of the insulation carrier and connected to the insulation carrier in a material-bonding manner.

9. The method of claim 8, wherein the dielectric insulation carrier is a ceramic platelet.

10. The method of claim 7, wherein each projection is formed as a projection of the carrier plate.

11. The method of claim 10, wherein each cutout is formed as a cutout in the lower metallization layer.

12. The method of claim 11, wherein the insulation carrier covers each cutout.

13. The method of claim 8, wherein the second metallization layer has a thickness in the range from 0.05 mm to 2.5 mm.

14. The method of claim 1, wherein the circuit carrier has an upper side populated with a semiconductor chip.
